(19) United States
(12) Patent Application Publication
(10) Pub. No.: US 2026/0114019 A1
(43) Pub. Date: Apr. 23, 2026

(54) SEMICONDUCTOR DEVICE AND MANUFACTURING METHOD BASED ON SEEDLESS SILICON SOURCE/DRAIN CONTACT RESISTANCE REDUCTION AND LASER PROCESS TECHNOLOGY

(71) Applicant: KOREA UNIVERSITY RESEARCH AND BUSINESS FOUNDATION, Seoul (KR)

(72) Inventors: Hyun-Yong YU, Seoul (KR); Jongyoun PARK, Seoul (KR); Euyjin PARK, Seoul (KR); Choong-hyun AHN, Seoul (KR); Sangsu LEE, Seoul (KR)

(21) Appl. No.: 19/363,427

(22) Filed: Oct. 20, 2025

(30) Foreign Application Priority Data
Oct. 18, 2024 (KR) 10-2024-0143384
Sep. 16, 2025 (KR) 10-2025-0132258

(51) Int. Cl. H10D 64/62; H01L 21/02; H01L 21/265; H01L 21/268; H01L 21/285

(52) U.S. Cl. CPC H10D 64/62; H10D 64/0112; H10P 14/3411; H10P 14/3814; H10P 30/204; H10P 30/21; H10P 34/42

(57) ABSTRACT

Disclosed are a semiconductor device based on seedless silicon (Si) source/drain contact resistance reduction and laser process technology and a method of fabricating the same. The semiconductor device includes an activated seedless Si layer formed on a substrate and at least one electrode formed on the seedless Si layer, and the seedless Si layer is crystalized through a first laser process and then activated through a second laser process.

### CROSS-REFERENCE TO RELATED APPLICATION(S)

This application claims the benefit under 35 USC § 119(a) of Korean Patent Application No. 10-2024-0143384 filed on Oct. 18, 2024 and Korean Patent Application No. 10-2025-0132258 filed on Sep. 16, 2025 in the Korean Intellectual Property Office, the entire disclosure of which is incorporated herein by reference for all purposes.

### BACKGROUND

### 1. Field

The present invention relates to technology for reducing a source/drain contact resistance of a semiconductor device and, more particularly, a method of fabricating a semiconductor device using a laser process that improves the performance of a semiconductor device by activating the same with a laser and the semiconductor device fabricated by the method.

### 2. Description of Related Art

In the existing semiconductor devices, source/drain (S/D) contact resistance is one of factors that significantly affect the device performance. In particular, in miniaturized devices, contact resistance is a main factor that hinders the overall performance. The conventional thermal processing method had limitations in significantly reducing resistance due to the difficulty in adjusting a bonding depth and a surface concentration. To address this issue, seedless silicon (Si)-based source/drain contact technology is attracting renewed attention. The present invention presents a solution of reducing resistance and maximizing the device performance by utilizing this seedless Si technology.

Monolithic 3D (M3D) integration enables high-performance, high-density logic devices, but suffers from thermal budget constraints, as conventional processes, such as rapid thermal annealing (RTA), degrade bottom-tier devices. To overcome this, the present invention proposes a fully laser-based fabrication approach that eliminates high-temperature processing in M3D top-layer complementary metal-oxide-semiconductor (CMOS) devices.

The key innovations of the present invention are as follows:

1. Seedless crystallization using a nucleation induction pattern forms a single-oriented Si channel and improves carrier mobility.

2. Laser-based source/drain (S/D) dopant activation achieves low contact resistance without RTA.

3. High ION/IOFF ratio (on-off current ratio) demonstrates the feasibility of high-performance logic application on an M3D top layer.

The device fabricated according to an example embodiment enhances the electrical performance while maintaining compatibility with M3D integration, ensuring the reliability of bottom-tier transistors.

### SUMMARY

The conventional high-temperature processing-based contact resistance reduction technology has been limited in their effective application in miniaturization due to process complexity and limitations in resistance reduction. The present invention aims to reduce the resistance and to prevent the degradation in device performance through a source/drain (S/D) contact structure using seedless silicon (Si).

A semiconductor device according to an example embodiment includes an activated seedless silicon (Si) layer formed on a substrate; and at least one electrode formed on the seedless Si layer, and the seedless Si layer is crystalized through a first laser process and then activated through a second laser process.

According to example embodiments, the following effects may be acquired.

Reduced contact resistance: Through a laser process, it is possible to reduce contact resistance using a significantly lower processing temperature than conventional methods and to significantly improve the device performance.

High-speed processing capability: It is possible to improve a switching speed of a device due to a reduction in contact resistance and to enable an efficient semiconductor operation through reduced power consumption.

Process simplification: Through a laser process, the existing complex thermal process and diffusion barrier are not required, which leads to saving process cost and improving mass production.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a semiconductor device according to an example embodiment;

FIG. 2 is a schematic process diagram of the semiconductor device illustrated in FIG. 1;

FIG. 3 is a flowchart illustrating a method of fabricating the semiconductor device illustrated in FIG. 1;

FIG. 4 illustrates the results of performing secondary ion mass spectrometry (SIMS) analysis after performing an ion implantation process;

FIG. 5 illustrates an image of patterned seedless silicon (Si) for results of a surface ablation test according to the laser power for dopant activation;

FIG. 6 illustrates the results of surface resistance and SIMS analysis using a 4-point-probe (4pp) method after laser activation;

FIG. 7 illustrates I/V characteristics in a metal-semiconductor (MS) contact structure after a laser activation process; and

FIG. 8 illustrates I/V characteristics of MS structure seedless Si to which an optimized laser activation process condition is applied.

### DETAILED DESCRIPTION

The aforementioned features and effects of the disclosure will be apparent from the following detailed description related to the accompanying drawings and accordingly those skilled in the art to which the disclosure pertains may easily implement the technical spirit of the disclosure.

Various modifications and/or alterations may be made to the disclosure and the disclosure may include various example embodiments. Therefore, some example embodiments are illustrated as examples in the drawings and described in detailed description. However, they are merely intended for the purpose of describing the example embodiments described herein and may be implemented in various forms. Therefore, the example embodiments are not construed as limited to the disclosure and should be understood to include all changes, equivalents, and replacements within the idea and the technical scope of the disclosure.

Although terms of “first,” “second,” and the like are used to explain various components, the components are not limited to such terms. These terms are used only to distinguish one component from another component.

For example, a first component may be referred to as a second component, or similarly, the second component may be referred to as the first component within the scope of the present disclosure. As used herein, the term “and/or” includes any and all combinations of one or more of the associated listed items.

As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Hereinafter, example embodiments will be described with reference to the accompanying drawings. However, the scope of the patent application is not limited to or restricted by such example embodiments. Like reference numerals used herein refer to like elements throughout.

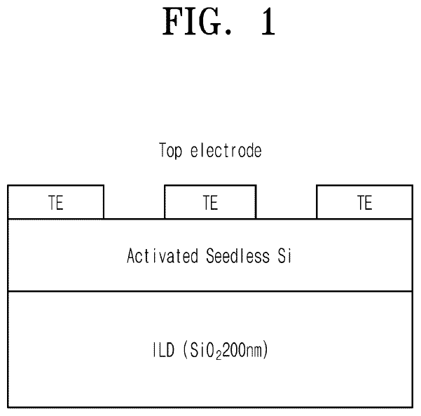

FIG. 1 illustrates a semiconductor device according to an example embodiment.

Referring to FIG. 1, the semiconductor device includes a transistor, a field effect transistor (FET), a metal-oxide-semiconductor FET (MOSFET), an inverter, a memory device, and a complementary metal-oxide-semiconductor (CMOS) device. The semiconductor device includes a substrate, an active layer, and at least one top electrode.

The substrate refers to a silicon (Si) substrate and may be implemented with SiO₂. Also, the substrate may function as an interlayer dielectric (ILD). In this case, an ILD layer is provided on a bottom device layer in a monolithic 3D (M3D) integration structure, and the bottom device layer and a top device layer are separated based on the ILD layer. According to an example embodiment, the ILD layer may have a thickness of about 200 nm.

The active layer formed on the substrate refers to an activated seedless Si layer, and may have a thickness of about 110 nm according to an example embodiment.

At least one top electrode formed on the active layer includes at least one of a source electrode, a drain electrode, and a gate electrode. According to an example embodiment, the source electrode and the drain electrode may be formed to be spaced apart from the gate electrode by providing the gate electrode therebetween. The at least one electrode may be implemented as a single layer, or may have a hierarchical structure that includes a plurality of layers. In the case of the hierarchical structure, a structure in which NiSi, Ti (or Mo), and Au are stacked or a structure in which Ti (or Mo) and Au are stacked from the active layer may be utilized. Also, depending on example embodiments, at least some of the plurality of layers may be omitted and/or the order between the layers may be changed.

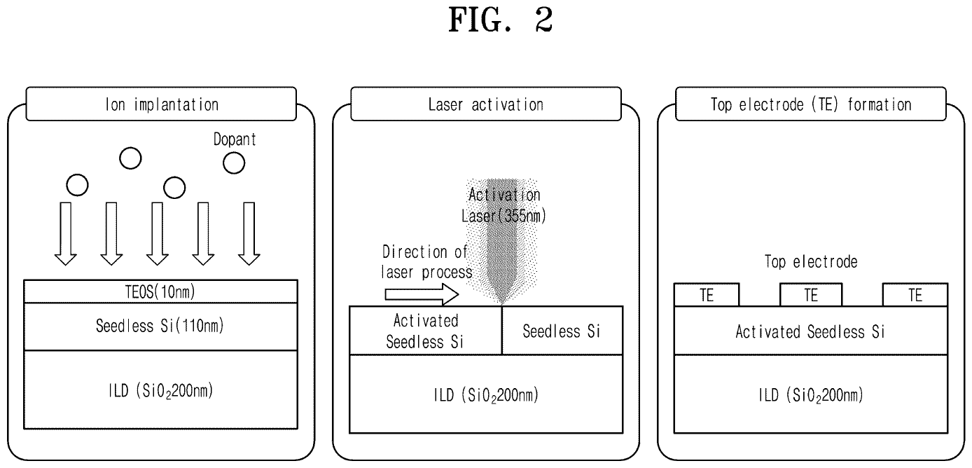

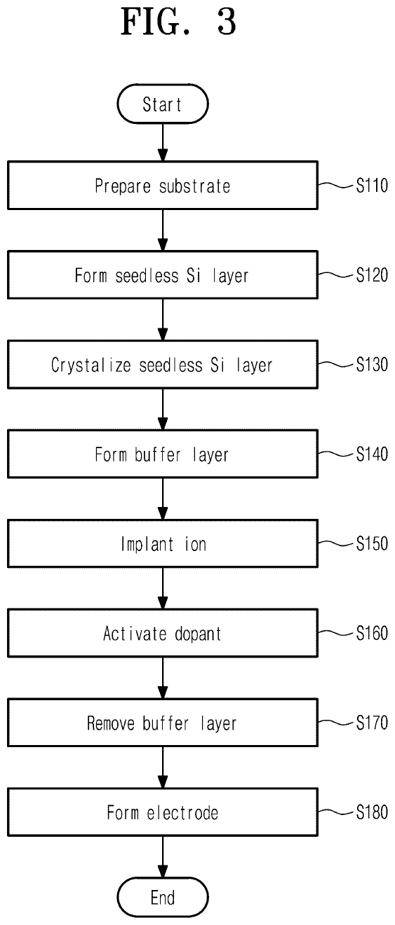

FIG. 2 is a schematic process diagram of the semiconductor device illustrated in FIG. 1, and FIG. 3 is a flowchart illustrating a method of fabricating the semiconductor device illustrated in FIG. 1.

Referring to FIGS. 1 to 3, an additional operation or process may be applied between operations specified in a process of fabricating the semiconductor device and the present invention does not exclude application of this additional operation or process. Also, the present invention may refer to an M3D top device or a top CMOS device and a method of fabricating the same.

In operation S110, a substrate is prepared. The substrate may be formed by depositing a Si substrate on a bottom device layer (e.g., bottom MOSFET layer) as an ILD layer. The ILD layer may electrically isolate the top device layer and/or the bottom device layer by electrically separating the bottom device layer and the top device layer.

In operation S120, a seedless Si layer is formed on the substrate. The seedless Si layer may be formed by depositing seedless Si on the substrate.

In operation S130, a crystallization is performed on the seedless Si layer. When crystallizing amorphous silicon using a laser, seedless Si may be crystallized using a continuous wavelength (CW) laser with the wavelength of about 532 nm according to an example embodiment.

In operation S140, a buffer layer, also called a screen layer, is formed. According to an example embodiment, the buffer layer may be formed by depositing tetraethyl orthosilicate (TEOS) with the thickness of about 10 nm on the seedless Si layer.

In operation S150, an ion implantation (or ion injection) process is performed. Exemplary conditions of the ion implantation process for implanting dopant are presented in Table 1 below.

TABLE 1

| | | | Dose | Power |
|---|---|---|---|---|
| Substrate | ILD | Dopant | (cm⁻²) | (keV) |
| Si | PECVD SiO₂ | Boron | 5.0 × 10¹⁵ | 10 |
| | (200 nm) | Phosphorous | | 15 |

The results of performing secondary ion mass spectrometry (SIMS) analysis after performing the ion implantation process using the conditions of Table 1 are shown in FIG. 4. Referring to FIG. 4, it can be seen that doping concentration peak appears within the depth of about 110 nm or less, the thickness of the top device (, which may indicate seedless Si layer).

In operation S160, an activation for the seedless Si layer is performed. According to an example embodiment, a pulsed laser with the wavelength of about 355 nm (more specifically, Nd:YAG 355-nm pulsed layer) may be used to electrically activate the dopant implanted into the seedless Si layer. By optimizing process conditions of the pulsed laser, the surface of seedless Si damaged by kinetic energy in the ion implantation process may be recrystallized.

This laser activation process may activate more dopant since the more heat is generated as the laser power increases. However, if the generated heat is excessive, a surface ablation phenomenon that the surface burns may occur, which may deteriorate the electrical property. Therefore, to search for the optimal laser activation power conditions for S/D dopant activation, a surface ablation test was performed by splitting the laser power as shown in Table 2.

TABLE 2

| | | | | Laser | Beam scan | Beam |
|---|---|---|---|---|---|---|
| | | | Laser | power | speed | size |
| Substrate | ILD | Dopant | type | (mJ/cm²) | (mm/s) | (um) |
| Si | PECVD | Boron | Nd: YAG | 80 | 0.3 | 150 × 10 |
| | SiO₂ | | 355 nm | 100 | | |
| | (50 nm) | Phosphorus | 30 ns | 120 | | |
| | | | 70 kHz | 140 | | |
| | | | Top-Hat | 160 | | |
| | | | beam | | | |

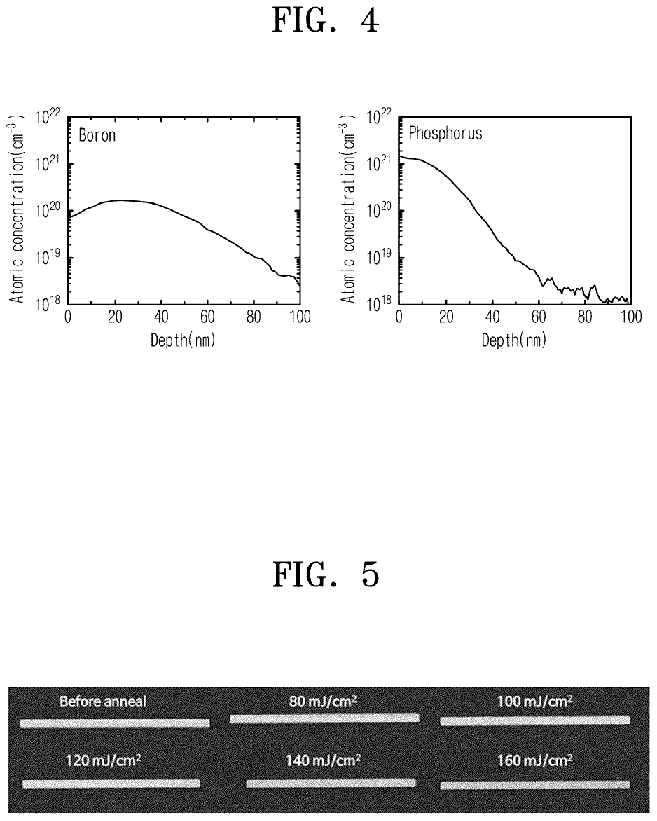

In this regard, FIG. 5 illustrates an image of patterned seedless Si for results of the surface ablation test according to the laser power. Referring to FIG. 5, for the laser power of 80 mJ/cm², the dopant activation effect is expected to be insignificant since no significant color change is observed compared to non-laser-activated Si. For the laser power of 160 mJ/cm², a relatively distinct color change is observed compared to non-laser-activated Si, but thermal damage is identified with the naked eye at the Si edge, which may deteriorate the electrical property.

Therefore, conditions of 100, 120, and 140 mJ/cm² are adopted to search for the optimal laser power. After laser activation is performed using the adopted conditions, surface resistance is extracted using a 4-point-probe (4pp) method to search for the optimal conditions.

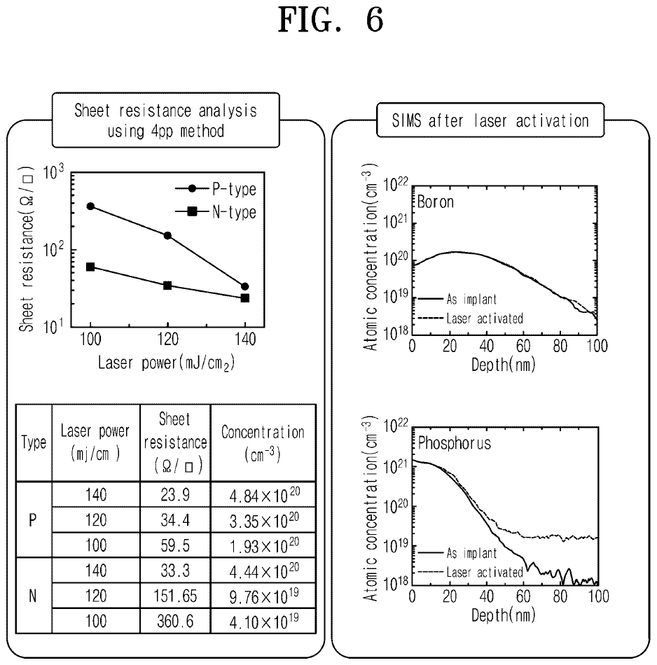

Using the sheet resistance measurement results, the dopant concentration was calculated for each laser power condition, and as shown in FIG. 6, it was about 10²⁰ cm⁻³ under all conditions, which satisfies a desired reference value (N>10¹⁸ cm⁻³). Also, as shown in FIG. 6, the lowest sheet resistance and the highest sheet resistance were measured at the laser power of 140 mJ/cm² and at the laser power of 100 mJ/cm², respectively.

To analyze a dopant profile after laser activation, SIMS analysis was performed at the maximum laser power (140 mJ/cm²) among the conditions adopted as shown in FIG. 6, which was verified to be consistent with the doping concentration calculation results through 4pp measurement. It was verified that neither top P-type Si nor N-type type Si exhibited excessive diffusion at the given laser power, and that the doping concentration peak appears within the depth of about 100 nm or less.

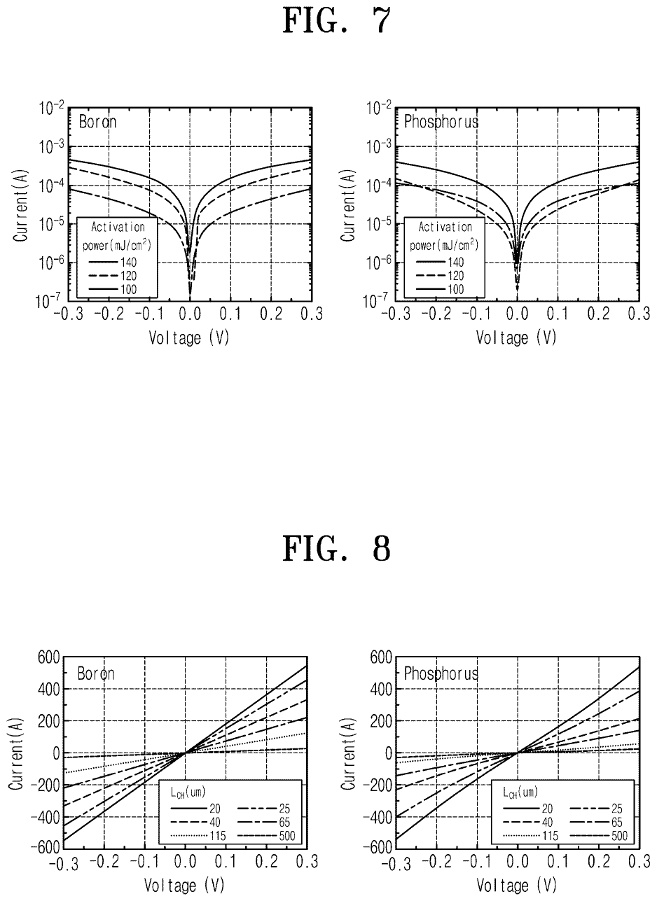

Electrical characteristic evaluation was performed to verify the optimal laser power conditions based on analysis data. As shown in FIG. 7, both P-type and N-type exhibited the highest conductivity at the maximum laser power (140 mJ/cm²), which is consistent with the trend of sheet resistance values measured at different laser power using the 4pp method. Therefore, it may be determined that the S/D area contact resistance of seedless Si will be lowest at the laser power of 140 mJ/cm².

As shown in FIG. 8, the contact resistance in the MS structure to which an e-beam evaporated Ti metal was applied was extracted using a transmission line metal (TLM) pattern under the corresponding laser power conditions. Table 3 below presents the contact resistance analysis results of the MS-structured seedless Si using the optimized laser activation process conditions. As shown in Table 3, the contact resistance of top Si was extracted as 2.63×10⁻⁶ for P-type and was extracted as 1.40×10⁻⁶ Ω·cm² for N-type.

TABLE 3

| | Laser power | Scan speed | Contact resistance |
|---|---|---|---|
| Dopant type | (mj/cm²) | (mm/s) | (Ω · cm²) |
| P-type | 140 | 0.3 | 2.63 × 10⁻⁶ |
| N-type | | | 1.40 × 10⁻⁶ |

Referring again to FIGS. 1 to 3, in operation S170, the buffer layer is removed. The buffer layer may be removed through a physical and/or chemical method. For example, by immersing a semiconductor device being fabricated in buffered oxide etchant (BOE) for a predetermined period of time (e.g., 10 seconds), only the buffer layer may be selectively removed.

In operation S180, at least one electrode is formed. The at least one electrode includes at least one of a source electrode, a drain electrode, and a gate electrode. The at least one electrode may be formed by depositing predetermined at least one metal on the seedless Si layer.

Here, to acquire lower contact resistance, NiSi may be applied to an S/D contact. When forming NiSi, 450° C., 30 sec conditions may be applied to evaporated Ni 15 nm using RTA.

As described above, according to example embodiments, it is possible to fabricate a semiconductor device through two laser processes without high-temperature processing.

While this disclosure includes specific example embodiments, it will be apparent to one of ordinary skill in the art that various alterations and modifications in form and details may be made in these example embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
an activated seedless silicon (Si) layer formed on a substrate; and
at least one electrode formed on the seedless Si layer,
wherein the seedless Si layer is crystalized through a first laser process and is activated through a second laser process.

2. The semiconductor device of claim 1, wherein the substrate is an interlayer dielectric (ILD) deposited on a bottom device layer in a monolithic three-dimensional (3D) (M3D) integration structure.

3. The semiconductor device of claim 2, wherein the first laser process uses a continuous wavelength (CW) laser with the wavelength of about 532 nm, and
the second laser process uses a pulsed laser with the wavelength of about 355 nm.

4. The semiconductor device of claim 3, wherein the semiconductor device is a transistor or a metal-oxide-semiconductor field effect transistor (MOSFET).

5. A method of fabricating a semiconductor device, the method comprising:
forming a seedless silicon (Si) layer on a substrate;
crystalizing the seedless Si layer through a first laser process;
forming a buffer layer on the seedless Si layer;
implanting dopant into the seedless Si layer;
activating the dopant through a second laser process;
removing the buffer layer; and
forming an electrode on the seedless Si layer.

6. The method of claim 5, wherein the substrate is an interlayer dielectric (ILD) deposited on a bottom device layer in a monolithic three-dimensional (3D) (M3D) integration structure.

7. The method of claim 6, wherein the first laser process uses a continuous wavelength (CW) laser with the wavelength of about 532 nm,
the second laser process uses a pulsed laser with the wavelength of about 355 nm, and
the buffer layer includes tetraethyl orthosilicate (TEOS).

8. The method of claim 7, wherein the dopant is boron (B) or phosphorus (P).

9. The method of claim 8, wherein the electrode includes NiSi, Ti, and Au or Ti and Au that are sequentially stacked.

10. The method of claim 9, wherein the electrode includes a source electrode, a drain electrode, and a gate electrode,
the source electrode and the drain electrode include NiSi, Ti, and Au that are sequentially stacked, and
the gate electrode includes Ti and Au that are sequentially stacked.
